(19) United States
(12) Patent Application Publication
(10) Pub. No.: US 2007/0295395 A1
(43) Pub. Date: Dec. 27, 2007

(54) Photovoltaic Device With Trimetaspheres

(75) Inventors: J. Paige Phillips, Hattiesburg, MS (US); Daniela M. Topasna, Lexington, VA (US); Steven A. Stevenson, Hattiesburg, MS (US); Pascal Deschatelets, Louisville, KY (US); Bryan Koene, Blacksburg, VA (US)

Correspondence Address: BUCHANAN, INGERSOLL & ROONEY PC, POST OFFICE BOX 1404, ALEXANDRIA, VA, 22313-1404, US

(73) Assignee: LUNA INNOVATIONS INCORPORATED, Roanoke, VA (US)

(21) Appl. No.: 10/594,073

(22) PCT Filed: Mar. 25, 2005
(86) PCT No.: PCT/US05/10214

§ 371 Date: Jun. 25, 2007

Related U.S. Application Data
(60) Provisional application No. 60/556,435, filed on Mar. 26, 2004.

(51) Int. Cl. H01L 31/04; H01L 31/0256; H01L 51/00

(52) U.S. Cl. 136/255

(57) ABSTRACT

An exemplary photovoltaic device for conversion of an incident wavelength of electromagnetic radiation to electricity has an absorber of incident wavelength of electromagnetic radiation, a trimetasphere in electron transferring contact with the absorber, an anode in electrical contact with the trimetasphere, and a cathode in electrical contact with the absorber. The absorber and trimetasphere can be arranged as a heterojunction or a blended junction. An exemplary electrical circuit has an absorber of incident electromagnetic radiation, a trimetasphere-containing material in electron transferring contact with the absorber, an anode, a cathode and a current path from the anode to the cathode. An exemplary method of converting incident electromagnetic radiation to an electrical signal using a trimetasphere-containing material is also disclosed.

### STATEMENT REGARDING FEDERALLY SPONSORED RESEARCH OR DEVELOPMENT

At least some aspects of this invention were made with Government support under the sponsorship of the Missile Defense Agency, Phase II SBIR contract no. DASG60-02-C-0043. The Government may have certain rights in this invention.

### TECHNICAL FIELD

This disclosure is related to photovoltaic materials and devices. More specifically, this disclosure is related to a photovoltaic device for conversion of an incident wavelength of electromagnetic radiation to electricity comprising a trimetasphere.

### BACKGROUND

In the discussion of the state of the art that follows, reference is made to certain structures and/or methods. However, the following references should not be construed as an admission that these structures and/or methods constitute prior art. Applicants expressly reserve the right to demonstrate that such structures and/or methods do not qualify as prior art against the present invention.

Organic thin film photovoltaic devices are usually composed of a photoactive polymer (such as poly(phenylene vinylene) or PPV) that generates an electron/hole pair (known as an exciton) upon absorption of a photon. In order to generate a photocurrent, the electrons and holes must be removed from each other to opposite electrodes. If these charges are not separated, recombination of the charges occurs, resulting in heat or radiation or other detrimental event.

A material with high electron affinity (such as Alcian blue) can accept the electronic charge to prevent this recombination and transfer it to an electrode to generate current. Classic fullerene materials, e.g., fullerene structures where the interior space is empty, and carbon nanotubes are known for their high electron affinity.

Despite their effectiveness in photovoltaic devices, the energy efficiency of classic fullerene materials has been poor compared with other photovoltaic technologies. Materials with improved electron affinity and mobility are required for improving overall solar energy conversion efficiency.

For example, classic fullerene materials and carbon nanotube materials are very non-polar and typically have poor miscibility with the photoactive polymers used in combination in the making of photovoltaic devices. One approach has been to form derivatives of these materials to promote higher compatibility. However, by derivatization the electronic properties of the materials, such as electron affinity, are compromised and the materials become less efficient as electron acceptors. PCBM (6,6)-phenyl-C₆₁-butyric acid is a fullerene derivative with an organic group to improve solubility and miscibility with the host material (for example, see T. Munters et al., Thin Solid Filmis, 403-404 (2002), pp. 247-251).

In another example, C₆₀ and other carbonaceous nanomaterials (classical fullerenes, classic metallofullerenes, e.g., a fullerene with one or more metal ions in an interior space (such as Gd⁺³@C₆₀), and carbon nanotubes) can readily react with environmental contaminants such as oxygen to produce singlet oxygen. Singlet oxygen can form epoxides or hydroxyls on the fullerene surface which contributes in disrupting the electronic properties of the materials. In the presence of visible radiative energy of approximately 500 to 700 nm, classical fullerenes such as C₆₀ may also under go internal dimerization (2+2 cycloaddition) reactions or polymerization reactions at elevated temperatures. In a photovoltaic cell, decreased efficiencies would result from the inevitable consumption of electron affinity material as described above.

### SUMMARY

An exemplary photovoltaic device for conversion of an incident wavelength of electromagnetic radiation to electricity comprises an absorber of the incident wavelength of electromagnetic radiation, a trimetasphere, the trimetasphere in electron transferring contact with the absorber, an anode in electrical contact with the trimetasphere, and a cathode in electrical contact with the absorber.

An exemplary electrical circuit comprises an absorber of incident electromagnetic radiation, a trimetasphere-containing material in electron transferring contact with the absorber, an anode, a cathode and a current path from the anode to the cathode.

A exemplary method of converting incident electromagnetic radiation to an electrical signal comprises absorbing the incident electromagnetic radiation by an absorber or a photoactive material to produce an electron-hole pair, transferring an electron in a Lowest Unoccupied Molecular Orbital (LUMO) of the absorber or the photoactive material across a band gap to a trimetasphere-containing material, injecting an electron from the trimetasphere-containing material into an anode, transferring a hole in a Highest Occupied Molecular Orbital (HOMO) of the absorber or the photoactive material to a cathode, and completing a circuit between the anode and the cathode.

### BRIEF DESCRIPTION OF THE DRAWINGS

The objects and advantages of the invention will become apparent from the following detailed description of preferred embodiments thereof in connection with the accompanying drawings in which like numerals designate like elements and in which:

FIG. 1 illustrates an exemplary embodiment of a Trimetasphere having an A¹A²A³N@C₈₀ structure.

FIG. 2 illustrates an exemplary calculated charge distribution in a Sc₃N@C₈₀ trimetasphere.

FIG. 3 illustrates an example of an energy level diagram for an exemplary embodiment of trimetasphere in an absorber host in an electrical circuit.

FIG. 4 is an exemplary embodiment of a photovoltaic device formed with trimetasphere material

FIG. 5 is a graph of normalized photoresponsivity as a function of wavelength for the device of FIG. 4.

### DETAILED DESCRIPTION

Trimetaspheres are a unique class of materials having unique electronic structures conferring highly efficient electron transport properties, increased oxidative, thermal, and radiative stability. Trimetaspheres are carbon-cage structures encapsulating one or more metal atoms or ions complexed with a nitrogen or other non-carbon heteroatom or ion in the interior space of the cage. When used in energy transfer applications, such as dopants in photovoltaic cells, efficient energy conversions can result.

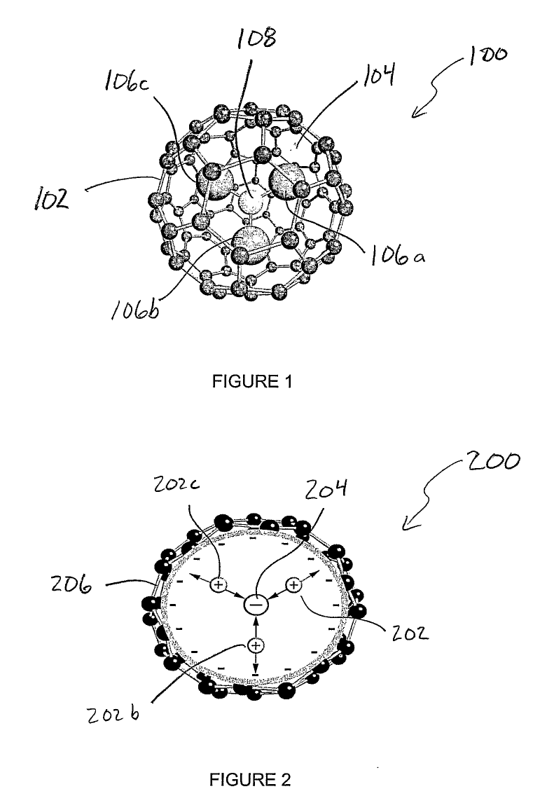

FIG. 1 illustrates an exemplary embodiment a trimetasphere. The trimetasphere 100 includes an outer cage 102 of carbon atoms. Within the cage 102 is an interior space 104 which contains one or more metal atoms or ions 106a, 106b, 106c that may be either a rare earth metal or a group IIIB metal. In the illustrated trimetasphere 100, the metal atom or ion is a trivalent ion and is located at the generally designated positions A¹, A², and A³ (corresponding to illustrated metal atoms or ions 106a, 106b, 106c, respectively). The metal atoms or ions 106a, 106b, 106c at each of the A¹, A², and A³ positions can be the same or different atoms or ions. Also illustrated is the complexed element 108. An example of the complexed element is nitrogen or other heteroatom or ion, such as phosphorous. The exemplary embodiment illustrated in FIG. 1 is a representative member (and the most abundant member) of this new class of materials. However, metal variations of the complex inside the cage and cage variations exist in this family of materials

Generally, the trimetaspheres suitable for use in this application have the general formula A₃₋ₙXₙN@Cₘ, where n ranges from 0 to 3, A and X may be trivalent metals and may be either a rare earth metal or a group IIIB metal, and m is between about 60 and about 200.

The size of the trimetasphere cage increases as the ionic radius for the metal increases. For example, to form a trimetasphere having a cage size at or below about 68, the metal atoms preferably have an ionic radius below about 0.090 nm (±0.005 nm). To form a trimetasphere metallofullerene having a cage size between about 68 carbon atoms and about 80 carbon atoms, the metal atoms are preferably trivalent and have an ionic radius below about 0.095 nm (±0.005 nm).

Preferably, the trimetasphere are selected from the A₃₋ₙXₙN@C₆₈, A₃₋ₙXₙN@C₇₈, or A₃₋ₙXₙN@C₈₀ families of endohedral fullerenes. Element A is selected from the group consisting of a rare earth element and a group IIIB element, preferably selected from the group consisting of Scandium, Yttrium, Lanthanum, Cerium, Praseodymium, Neodymium, Gadolinium, Terbium, Dysprosium, Holmium, Erbium, Thulium, and Ytterbium; and more preferably selected from the group consisting of Erbium, Holmium, Scandium and Yttrium. Preferably, Element X is selected from the group consisting of a rare earth element and a group IIIB element preferably selected from the group consisting of Scandium, Yttrium, Lanthanum, Cerium, Praseodymium, Neodymium, Gadolinium, Terbium, Dysprosium, Holmium, Erbium, Thulium, and Ytterbium, and more preferably is Scandium.

As used herein, “endohedral” refers to the encapsulation of atoms inside the carbon cage network. Accepted symbols for elements and subscripts to denote numbers of elements are used herein. Further, all elements to the right of an @ symbol are part of the carbon cage network, while all elements listed to the left are contained within the carbon cage network. Under this notation, Sc₃N@C₈₀ indicates that the Sc₃N trimetallic nitride is situated within a C₈₀ carbon cage.

The electronic structure of the trimetasphere distinguishes it from classical fullerenes and classic metallofullerenes due to the encapsulated metal-heteroatom/ion complex. The complex confers novel electronic properties resulting in superior electron accepting (ease of reduction) and electron transfer (high mobility) properties. The formal charge assignment in these materials suggests a charge disparity among the component materials. As an example, FIG. 2 illustrates the charge distribution in a C₈₀ carbon cage. The charge distribution (negative—positive—negative) of the different zones (cage—metal atom/ion—complexed heteroatom/ion) of the trimetasphere contributes to impart unique properties. In the illustrated trimetasphere 200 of FIG. 2, the metal atom/ion 202a, 202b, 202c is a trivalent group IIIB element and each contributes one electron to the complexed heteroatom/ion 204 (for example nitrogen) for bonding and contributes two electrons to the carbon cage 206 for charge balance. The resulting charge distribution on the trimetasphere 200 includes a negative—positive—negative charge distribution of the cage—metal atom/ion—complexed heteroatom/ion, respectively.

Trimetasphere materials have significantly different physical properties and limitations as potential electron accepting materials for electro-optic devices. Trimetaspheres are more polar (polarizable) than classical carbonaceous nanomaterials, as demonstrated by their increased solubility in more polar solvents, and increased retention times on separation media that discriminates according to polarizability and compound polarity. As a result unanticipated advantages may be realized in system compatibility and miscibility with cell components, in the place of the less polar classical fullerenes and nanotubes. For example, the external fullerene cage in the trimetasphere material is relatively non-reactive in comparison to classical metallofullerene and has a much higher thermal stability than traditional fullerene materials.

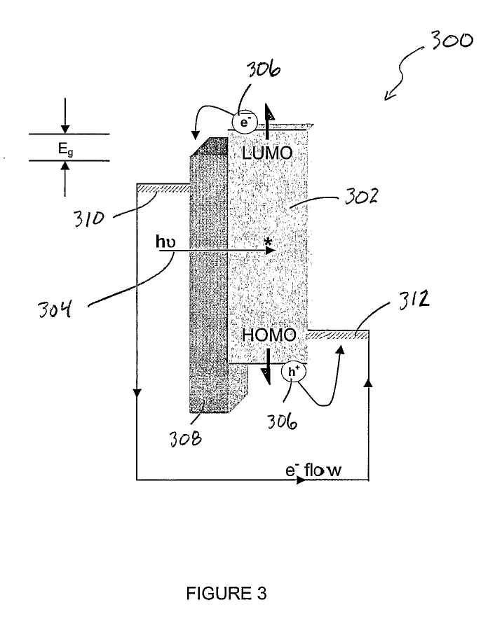

Trimetasphere can be used in photovoltaic devices. FIG. 3 shows an exemplary combined energy level diagram/circuit diagram 300 including a trimetasphere. The absorber or photoactive material 302 absorbs radiation 304 (e.g. visible or ultraviolet), producing an electron-hole pair (exciton) 306. The electron (e⁻) in the Lowest Unoccupied Molecular Orbital (LUMO) of the absorber 302 can be transferred across the band gap (E_{g}) to the LUMO of the trimetasphere or trimetasphere-containing material 308. This electron can then be injected into the anode 310. The hole (h⁺) remaining in the Highest Occupied Molecular Orbital (HOMO) of the absorber 302 can be transferred to the cathode 312, thus completing the circuit. This transfer can be direct, or alternatively mediated by another material with electron/hole mobility properties, such as poly-3,4-ethylenedioxythiophene (PEDOT). A dispersing aid such as polystyrene sulfonate (PSS) may also be used. Although FIG. 3 illustrates a heterojunction arrangement, other arrangements are contemplated herein including blended junctions.

The absorber can be any photoactive material (polymer, molecular organic, inorganic, etc.) or combination of materials, which can absorb photons to generate an exciton; the trimetasphere can be any trimetasphere disclosed herein; and the anode (and cathodes) can be any electronically conductive material, such as a metal or semiconductor, with a work function that allows accepting or donating an electron from the bulk materials.

Differing electronic properties are to be expected for variations of trimetaspheres having alternative structures than those depicted in FIGS. 1-3 and particularly with different atoms from the periodic table. Likewise variations of carbon cage structures including, but not limited to, C₆₀, C₇₀, C₇₈, C₈₂, C₈₄, C₈₆, C₈₈, C₉₀, and C₉₂ will each have differing electronic, physical, and structural properties that will affect the resultant application.

Trimetaspheres can be incorporated into polymer based photovoltaic devices by any suitable means, including heterojunction devices and blended devices.

For example, trimetaspheres can be spin coated with conducting polymers, such as polythiophene and PPV, onto conductive or semiconductive substrates, such as indium-tin-oxide (ITO) coated glass or metal electrodes, e.g., aluminum, to form a surface contact between the trimetasphere and the absorber, e.g., a heterojunction. In another example, trimetaspheres have been vapor deposited at elevated temperatures in a reduced atmosphere onto conductive or semiconductive substrates. Optionally, to provide an electrical contact, metal electrodes can be deposited onto the trimetasphere material.

In another example, the trimetasphere/absorber mixture can be deposited by any method in which the two materials can be blended to form a blended junction. Examples of these methods include, but are not limited to: (a) dissolving both materials in a solvent and casting a film on a substrate (e.g. electrode) via spin coating, dip coating, etc.; (b) trimetasphere can be vapor deposited onto films of the absorber host; (c) trimetasphere and absorbers can be co-deposited by vapor deposition or similar process; and (d) alternate layers of trimetasphere/absorber can be deposited via molecular self assembly processes. Mixtures of the trimetasphere/absorber can be homogeneous, or deposited with a concentration gradient through the material.

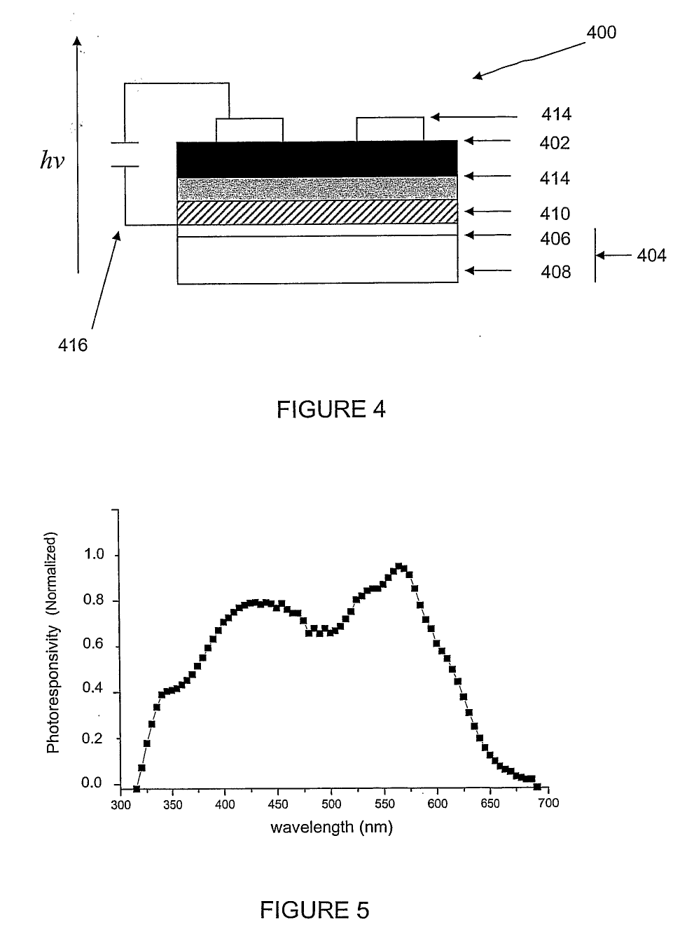

Some of these example methods have been tested for photocurrent measurements with applied voltage bias while exposed to light and dark conditions. FIG. 4 is an exemplary embodiment of a device incorporating trimetasphere material. In the FIG. 4 device 400, an approximately 100 nm trimetasphere layer 402 is deposited onto an ITO substrate 404. The Figure illustrates both the glass portion 406 and the indium-tin-oxide layer 408 of the ITO substrate 404. The device 400 also includes a layer of an electron/hole mobile material PEDOT:PSS 410 and a layer (approximately 100 nm) of polythiophene 412 as an absorber material. To complete the device, aluminum electrodes 414 and a circuit 416 from the aluminum electrodes to the indium-tin-oxide layer 408 are included. FIG. 5 is a graph of normalized photoresponsivity as a function of wavelength for the device of FIG. 4.

In another exemplary embodiment, the outside of the carbon cage is derivatized with an organic group. These organic groups can affect the solubility of the trimetasphere, or make them compatible with one or more other components, such as the absorber. The derivatization changes both the ability of the trimetasphere to disperse into another material as well as the electronic properties of the structure of the trimetasphere.

Applications of these materials include applications and devices in which electron and energy transfer can be enabled or enhanced. For example: photovoltaic devices, thermo-electrics, light emitting diodes, capacitors, and transistors use the electronic principles discussed herein to operate. Each of these applications can be adapted to incorporate trimetaspheres.

Further details concerning trimetaspheres, their material characteristics and their uses may be found in U.S. Pat. No. 6,303,760, the entire disclosure of which is herein incorporated by reference.

Although the present invention has been described in connection with preferred embodiments thereof, it will be appreciated by those skilled in the art that additions, deletions, modifications, and substitutions not specifically described may be made without department from the spirit and scope of the invention as defined in the appended claims.

What is claimed is:

1. A photovoltaic device for conversion of an incident wavelength of electromagnetic radiation to electricity, the photovoltaic device comprising:
an absorber of the incident wavelength of electromagnetic radiation;
a trimetasphere, the trimetasphere in electron transferring contact with the absorber;
an anode in electrical contact with the trimetasphere; and
a cathode in electrical contact with the absorber.

2. The photovoltaic device of claim 1, wherein the absorber and trimetasphere are a heterojunction.

3. The photovoltaic device of claim 1, wherein the absorber and trimetasphere are a blended junction

4. The photovoltaic device of claim 1, wherein the trimetasphere includes a carbon-cage structure with an interior volume, wherein the carbon-cage structure encapsulates one or more metal atoms or ions complexed with a non-carbon heteroatom or ion.

5. The photovoltaic device of claim 4, wherein the trimetasphere has a general formula A₃₋ₙXₙN@Cₘ, wherein n ranges from 0 to 3, A and X are a trivalent metal, m is between about 60 and about 200, and N is the non-carbon heteroatom or ion.

6. The photovoltaic device of claim 5, wherein N is nitrogen.

7. The photovoltaic device of claim 5, wherein the trivalent metal is a rare earth metal or a group IIIB metal.

8. The photovoltaic device of claim 7, wherein A is selected from the group consisting of Scandium, Yttrium, Lanthanum, Cerium, Praseodymium, Neodymium, Gadolinium, Dysprosium, Holmium, Erbium, Thulium, and Ytterbium.

9. The photovoltaic device of claim 8, wherein A is selected from the group consisting of Erbium, Holmium, Scandium and Yttrium.

10. The photovoltaic device of claim 7, wherein X is selected from the group consisting of Scandium, Yttrium, Lanthanum, Cerium, Praseodymium, Neodymium, Gadolinium, Dysprosium, Holmium, Erbium, Thulium, and Ytterbium.

11. The photovoltaic device of claim 1, wherein the trimetasphere has a A¹, A², A³ complexed structure where A¹, A², and A³ are the same atoms or ions.

12. The photovoltaic device of claim 11, wherein the trimetasphere has a A¹, A², A³ complexed structure including a heteroatom or ion.

13. An electrical circuit comprising:
an absorber of incident electromagnetic radiation;
a trimetasphere-containing material in electron transferring contact with the absorber;
an anode;
a cathode; and
a current path from the anode to the cathode.

14. The electrical circuit of claim 13, wherein the absorber and trimetasphere-containing material are a heterojunction.

15. The electrical circuit of claim 13, wherein the absorber and trimetasphere-containing material are a blended junction.

16. The electrical circuit of claim 13, wherein the anode is in electrical contact with the trimetasphere-containing material.

17. The electrical circuit of claim 13, wherein the cathode is in electrical contact with the absorber.

18. The electrical circuit of claim 13, wherein a trimetasphere in the trimetasphere-containing material includes a carbon-cage structure with an interior volume, wherein the carbon-cage structure encapsulates one or more metal atoms or ions complexed with a non-carbon heteroatom or ion.

19. The electrical circuit of claim 18, wherein the trimetasphere has a general formula A₃₋ₙXₙN@Cₘ, wherein n ranges from 0 to 3, A and X are a trivalent metal, m is between about 60 and about 200, and N is the non-carbon heteroatom or ion.

20. The electrical circuit of claim 19, wherein N is nitrogen.

21. The electrical circuit of claim 19, wherein the trivalent metal is a rare earth metal or a group IIIB metal.

22. The electrical circuit of claim 21, wherein A is selected from the group consisting of Scandium, Yttrium, Lantharium, Cerium, Praseodymium, Neodymium, Gadolinium, Dysprosium, Holmium, Erbium, Thulium, and Ytterbium.

23. The electrical circuit of claim 22, wherein A is selected from the group consisting of Erbium, Holmium, Scandium and Yttrium.

24. The electrical circuit of claim 21, wherein X is selected from the group consisting of Scandium, Yttrium, Lantharium, Cerium, Praseodymium, Neodymium, Gadolinium, Dysprosium, Holmium, Erbium, Thulium, and Ytterbium.

25. The electrical circuit of claim 13, wherein a trimetasphere of the trimetasphere-containing material has a A¹, A², A³ complexed structure where A¹, A², and A³ are the same atoms or ions.

26. The electrical circuit of claim 25, wherein the trimetasphere has a A¹, A², A³ complexed structure including a heteroatom or ion.

27. A method of converting incident electromagnetic radiation to an electrical signal, the method comprising:
absorbing the incident electromagnetic radiation by an absorber or a photoactive material to produce an electron-hole pair;
transferring an electron in a Lowest Unoccupied Molecular Orbital (LUMO) of the absorber or the photoactive material across a band gap to a trimetasphere-containing material;
injecting an electron from the trimetasphere-containing material into an anode
transferring a hole in a Highest Occupied Molecular Orbital (HOMO) of the absorber or the photoactive material to a cathode; and
completing a circuit between the anode and the cathode.

28. The method of claim 27, wherein the absorber and the trimetasphere-containing material are a heterojunction.

29. The method of claim 27, wherein the absorber and the trimetasphere-containing material are a blended junction.

30. The method of claim 27, wherein a trimetasphere in the trimetasphere-containing material includes a carbon-cage structure with an interior volume, wherein the carbon-cage structure encapsulates one or more metal atoms or ions complexed with a non-carbon heteroatom or ion.

31. The method of claim 30, wherein the trimetasphere has a general formula A₃₋ₙXₙN@Cₘ, wherein n ranges from 0 to 3, A and X are a trivalent metal, m is between about 60 and about 200, and N is the non-carbon heteroatom or ion.

32. The method of claim 31, wherein N is nitrogen.

33. The method of claim 31, wherein the trivalent metal is a rare earth metal or a group IIIB metal.

34. The method of claim 33, wherein A is selected from the group consisting of Scandium, Yttrium, Lanthanum, Cerium, Praseodymium, Neodymium, Gadolinium, Dysprosium, Holmium, Erbium, Thulium, and Ytterbium.

35. The method of claim 34, wherein A is selected from the group consisting of Erbium, Holmium, Scandium and Yttrium.

36. The method of claim 33, wherein X is selected from the group consisting of Scandium, Yttrium, Lanthanum, Cerium, Praseodymium, Neodymium, Gadolinium, Dysprosium, Holmium, Erbium, Thulium, and Ytterbium.

37. The method of claim 27, wherein the incident electromagnetic radiation is a wavelength in a visible spectrum or an ultraviolet spectrum.

38. The method of claim 27, wherein a trimetasphere of the trimetasphere-containing material has a A¹, A², A³ complexed structure where A¹, A², and A³ are the same atoms or ions.

39. The method of claim 38, wherein the trimetasphere has a A¹, A², A³ complexed structure including a heteroatom or ion.
